(19) United States
(12) Patent Application Publication
(10) Pub. No.: US 2025/0008651 A1
(43) Pub. Date: Jan. 2, 2025

(54) PRINTED WIRING BOARD

(71) Applicant: IBIDEN CO., LTD., Ogaki (JP)

(72) Inventors: Susumu KAGOHASHI, Ogaki (JP); Jun SAKAI, Ogaki (JP)

(73) Assignee: IBIDEN CO., LTD., Ogaki (JP)

(21) Appl. No.: 18/753,887

(22) Filed: Jun. 25, 2024

(30) Foreign Application Priority Data
Jun. 27, 2023 (JP) 2023-105450

(51) Int. Cl. H05K 1/11; H05K 1/03; H05K 3/16; H05K 3/42

(52) U.S. Cl. CPC H05K 1/115; H05K 1/0366; H05K 3/16; H05K 3/429; H05K 2201/09845

(57) ABSTRACT

A printed wiring board includes a first conductor layer, an insulating layer formed on the first conductor, a second conductor layer formed on the insulating layer, and a via conductor formed in the insulating layer such that the via conductor is penetrating through the insulating layer and connecting the first and second conductor layers. The insulating layer has a via hole in which the via conductor is formed such that inner wall surface in the via hole has a first inclined surface decreasing in diameter from the second conductor layer to a middle portion of the via hole in a thickness direction of the insulating layer, a second inclined surface decreasing in diameter from the middle portion to the first conductor layer with a smaller diameter than an end part of the first inclined surface in the middle portion, and a step surface connecting the first and second inclined surfaces.

### CROSS-REFERENCE TO RELATED APPLICATIONS

The present application is based upon and claims the benefit of priority to Japanese Patent Application No. 2023-105450, filed Jun. 27, 2023, the entire contents of which are incorporated herein by reference.

### BACKGROUND OF THE INVENTION

### Field of the Invention

The present invention relates to a printed wiring board.

### Description of Background Art

Japanese Patent Application Laid-Open Publication No. 2009-302588 describes a multilayer printed wiring board in which interlayer resin insulating layers and conductor circuits are alternately laminated. The entire contents of this publication are incorporated herein by reference.

### SUMMARY OF THE INVENTION

According to one aspect of the present invention, a printed wiring board includes a first conductor layer, a resin insulating layer formed on the first conductor, a second conductor layer formed on the resin insulating layer, and a via conductor formed in the resin insulating layer such that the via conductor is penetrating through the resin insulating layer and connecting the first conductor layer and the second conductor layer. The resin insulating layer has a via hole in which the via conductor is formed such that an inner wall surface in the via hole has a first inclined surface decreasing in diameter from the second conductor layer to a middle portion of the via hole in a thickness direction of the resin insulating layer, a second inclined surface decreasing in diameter from the middle portion to the first conductor layer with a smaller diameter than an end part of the first inclined surface in the middle portion, and a step surface connecting the first inclined surface and the second inclined surface.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating a printed wiring board according to an embodiment of the present invention;

FIG. 2A is a partially enlarged cross-sectional view illustrating a printed wiring board according to an embodiment of the present invention;

FIG. 2B is a partially enlarged cross-sectional view illustrating a printed wiring board according to an embodiment of the present invention;

FIG. 2C is a partially enlarged cross-sectional photograph showing a printed wiring board according to an embodiment of the present invention;

FIG. 3A is a cross-sectional view illustrating an example of a manufacturing process of a printed wiring board according to an embodiment of the present invention;

FIG. 3B is a cross-sectional view illustrating an example of a manufacturing process of a printed wiring board according to an embodiment of the present invention;

FIG. 3C is a cross-sectional view illustrating an example of a manufacturing process of a printed wiring board according to an embodiment of the present invention;

FIG. 3D is a cross-sectional view illustrating an example of a manufacturing process of a printed wiring board according to an embodiment of the present invention;

FIG. 3E is a cross-sectional view illustrating an example of a manufacturing process of a printed wiring board according to an embodiment of the present invention;

FIG. 3F is a cross-sectional view illustrating an example of a manufacturing process of a printed wiring board according to an embodiment of the present invention;

FIG. 3G is a cross-sectional view illustrating an example of a manufacturing process of a printed wiring board according to an embodiment of the present invention;

FIG. 3H is a cross-sectional view illustrating an example of a manufacturing process of a printed wiring board according to an embodiment of the present invention; and

FIG. 3I is a cross-sectional view illustrating an example of a manufacturing process of a printed wiring board according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

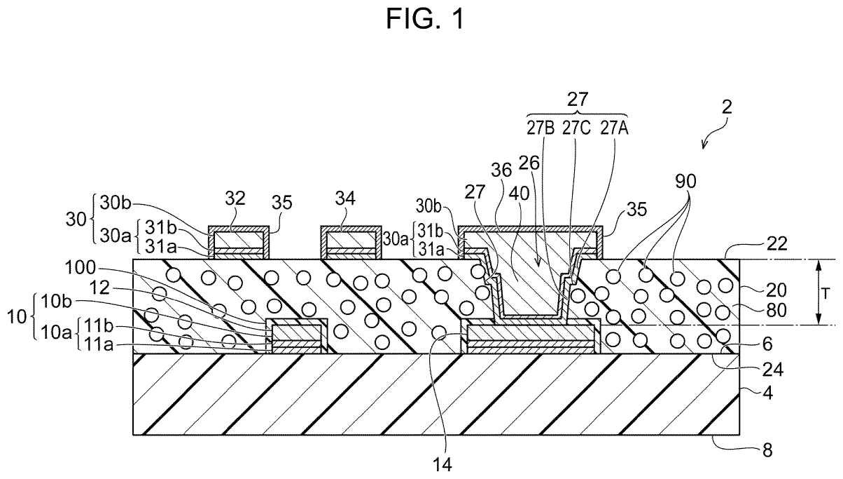

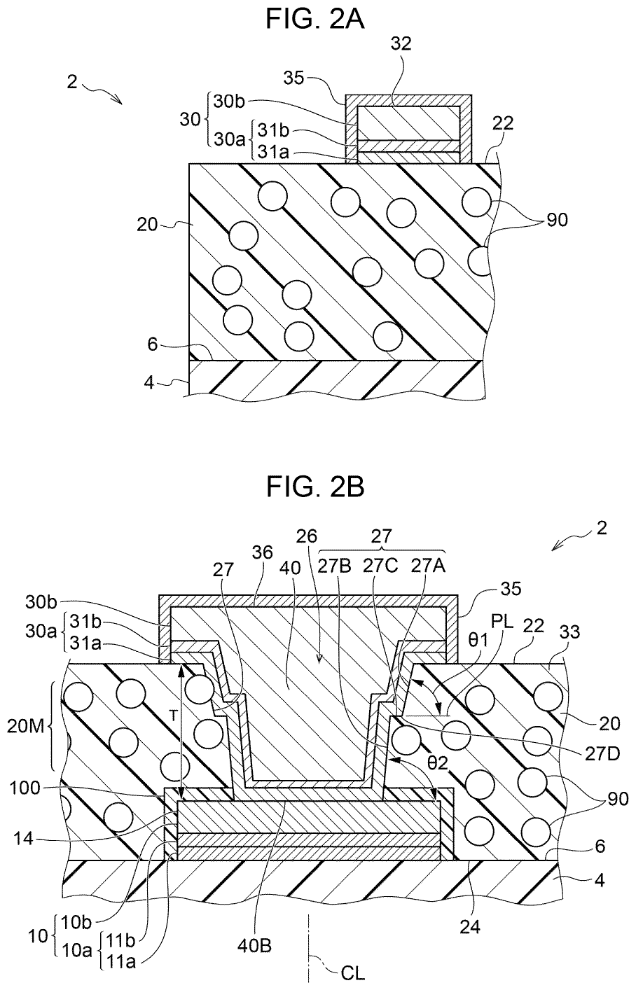

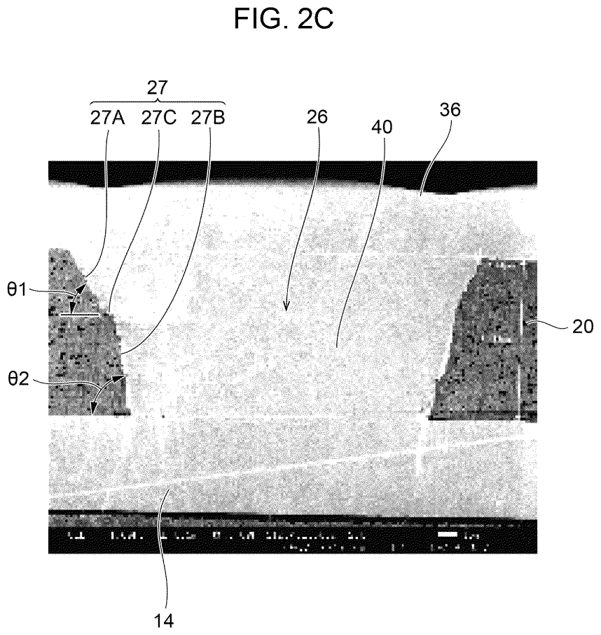

FIG. 1 is a cross-sectional view illustrating a printed wiring board 2 of an embodiment. FIGS. 2A and 2B are each an enlarged cross-sectional view illustrating a part of the printed wiring board 2 of the embodiment. As illustrated in FIG. 1, the printed wiring board 2 includes an insulating layer 4, a first conductor layer 10, a resin insulating layer 20, a second conductor layer 30, and a via conductor 40.

The insulating layer 4 is formed using a resin. The insulating layer 4 may contain inorganic particles such as silica particles. The insulating layer 4 may contain a reinforcing material such as a glass cloth. The insulating layer 4 has a third surface 6 (upper surface in the drawing) and a fourth surface 8 (lower surface in the drawing) on the opposite side with respect to the third surface 6.

The first conductor layer 10 is formed on the third surface 6 of the insulating layer 4. The first conductor layer 10 includes a signal wiring 12 and a pad 14. The first conductor layer 10 may also include a conductor circuit other than the signal wiring 12 and the pad 14. The first conductor layer 10 is mainly formed of copper. The first conductor layer 10 is formed of a seed layer (10a) on the insulating layer 4 and an electrolytic plating layer (10b) on the seed layer (10a). The seed layer (10a) is formed of a first layer (11a) on the third surface 6 and a second layer (11b) on the first layer (11a). The first layer (11a) is formed of an alloy (copper alloy) containing copper, silicon and aluminum. The second layer (11b) is formed of copper. The electrolytic plating layer (10b) is formed of copper. The first layer (11a) is in contact with the insulating layer 4.

In the first conductor layer 10, a portion that is not in contact with the third surface 6 of the insulating layer 4 is a surface of the first conductor layer 10. The surface of the first conductor layer 10 includes a first surface and a second surface. The first surface is a surface exposed from the via hole 26 of the resin insulating layer 20. The second surface is a portion of the surface of the first conductor layer 10 that is not the first surface. The first surface is not covered by an adhesive layer 100. The second surface is a portion that is covered by the adhesive layer 100. The adhesive layer 100 is formed of a nitrogen-based organic compound. The nitrogen-based organic compound forming the adhesive layer 100 is, for example, a tetrazole compound. The nitrogen-based organic compound may be a tetrazole compound described in Japanese Patent Application Laid-Open Publication No. 2015-54987. The adhesive layer 100 covers the second surface of the first conductor layer 10 but does not cover the third surface 6 exposed from the first conductor layer 10.

The resin insulating layer 20 is formed on the third surface 6 of the insulating layer 4 and on the first conductor layer 10. The resin insulating layer 20 is formed on the first conductor layer 10 with the adhesive layer 100 in between. The resin insulating layer 20 has a first surface 22 (upper surface in the drawing) and a second surface 24 (lower surface in the drawing) on the opposite side with respect to the first surface 22. The first conductor layer 10 extend to an inner side of the second surface 24 of the resin insulating layer 20. The second surface 24 of the resin insulating layer 20 faces the first conductor layer 10 via a portion that is in contact with upper and side surfaces of the first conductor layer 10 in the drawing. The resin insulating layer 20 contains a resin 80 and a large number of inorganic particles 90. For the resin 80, for example, a thermosetting resin or a photocurable resin may be used. For the resin 80, as an example, an epoxy resin is used. The large number of inorganic particles 90 are dispersed in the resin 80. For the inorganic particles 90, for example, silica or alumina particles may be used. The inorganic particles 90 have, for example, an average particle size of 0.5 μm and particle sizes in a range of 0.1 μm or more and 5.0 μm or less. The resin insulating layer 20 has a via hole 26 as a through hole that penetrates the resin insulating layer 20 in a thickness direction. An inner wall surface 27 of the via hole 26 is formed of the resin 80 and the inorganic particles 90.

As illustrated in FIG. 2A, the first surface 22 of the resin insulating layer 20 is formed only of the resin 80. No inorganic particles 90 are exposed from the first surface 22. Specifically, the first surface 22 does not include surfaces of the inorganic particles 90. No unevenness is formed on the first surface 22 of the resin insulating layer 20. The first surface 22 is not roughened. The first surface 22 is formed smooth. The first surface 22 has, for example, an arithmetic mean roughness (Ra) of 0.02 μm or more and 0.06 μm or less.

On the other hand, some of the inorganic particles 90 are exposed on the inner wall surface 27 of the via hole 26. The inner wall surface 27 of the via hole 26 includes surfaces of the inorganic particles 90. The inner wall surface 27 of the via hole 26 has unevenness. The inner wall surface 27 of the via hole 26 is formed of an exposed surface of the resin 80 and exposed surfaces of the inorganic particles 90. The inner wall surface 27 of the via hole 26 is a non-roughened surface and is not roughened. The arithmetic mean roughness (Ra) of the inner wall surface 27 of the via hole 26 is, for example, in a range of 0.005 μm or more and 0.1 μm or less.

A thickness of the resin insulating layer 20 is two or more times a thickness of the second conductor layer 30. The thickness (T) of the resin insulating layer 20 is a distance between the first surface 22 and the upper surface of the first conductor layer 10. In the resin insulating layer 20, a region with a thickness ranging from 20% to 80% of the thickness (T) from the first surface 22 is a middle portion (20M) in the thickness direction of the resin insulating layer 20.

As shown in FIGS. 2B and 2C, the inner wall surface 27 of the via hole 26 includes a first inclined surface (27A), a second inclined surface (27B), and a step surface (27C). In the first inclined surface (27A), the inner wall surface 27 of the via hole 26 decreases in diameter from the first surface 22 side to the middle portion (20M). An end part (lower end part in the figures) of the first inclined surface (27A) on the middle portion (20M) side in the thickness direction of the resin insulating layer 20 is an end part (27D). The end part (27D) is a portion with a smallest diameter in the first inclined surface (27A). The second inclined surface (27B) has a smaller diameter than the end part (27D). That is, the entire second inclined surface (27B) has a smaller diameter than the first inclined surface (27A). Compared to a structure where, for example, the first inclined surface (27A) extends all the way to the pad 14 without having the second inclined surface (27B), a bottom part of the via hole 26 is increased in diameter. A bottom part (40B) of the via conductor 40 also is increased in diameter.

In the second inclined surface (27B), the inner wall surface 27 of the via hole 26 decreases in diameter from the middle portion (20M) to the second surface 24 (the pad 14 side). The step surface (27C) is a surface that continuously connects between the first inclined surface (27A) and the second inclined surface (27B). The step surface (27C) is a step relative to the first inclined surface (27A) and the second inclined surface (27B). The step surface (27C) is positioned in a vertical direction within the range of the intermediate portion (20M).

FIG. 2B is a cross section that includes a center line (CL) of the via hole 26. In this cross section, the second inclined surface (27B) is inclined with respect to the upper surface of the first conductor layer 10. The first inclined surface (27A) is inclined with respect to a parallel plane (PL) that is parallel to the upper surface of the first conductor layer 10. In effect, the first inclined surface (27A) is also inclined with respect to the upper surface of the first conductor layer 10. An inclination angle of the first inclined surface (27A) with respect to the parallel plane (PL) is referred to as a first inclination angle (θ1). An inclination angle of the second inclined surface (27B) with respect to the upper surface of the first conductor layer 10 is referred to as a second inclination angle (θ2). The second inclination angle (θ2) is larger than the first inclination angle (θ1). The first inclination angle (θ1) is, for example, 75 degrees or more and less than 85 degrees. The second inclination angle (θ2) is, for example, 85 degrees or more and less than 89 degrees.

The second inclination angle (θ2) of the second inclined surface (27B) is larger than the first inclination angle (θ1) of the first inclined surface (27A). Compared to a structure where the second inclination angle (θ2) of the second inclined surface (27B) is equal to or smaller than the first inclination angle (θ1) of the first inclined surface (27A), the bottom part (26B) of the via hole 26 is increased in diameter. The bottom part (40B) of the via conductor 40 also is increased in diameter.

In the cross section illustrated in FIG. 2B, the step surface (27C) is parallel to the upper surface of the first conductor layer 10. The step surface (27C) may be inclined with respect to the upper surface of the first conductor layer 10. An inclination angle of the step surface (27C) with respect to the upper surface of the first conductor layer 10 is referred to as a third inclination angle (θ3). The third inclination angle (θ3) is, for example, 5 degrees or more and 30 degrees or less. When the third inclination angle (θ3) is a positive value, the step surface (27C) is inclined in the same direction as the first inclined surface (27A) and the second inclined surface (27B). When the third inclination angle (θ3) is a negative value, the step surface (27C) is inclined in the opposite direction to the first inclined surface (27A) and the second inclined surface (27B). When the third inclination angle (θ3) is zero, the step surface (27C) is parallel to the upper surface of the first conductor layer 10.

Compared to a structure where the second inclined surface (27B) extends continuously from the end part (27D) of the first inclined surface (27A) without having a step surface (27C), the bottom part of the via hole 26 is decreased in diameter. The bottom part (40B) of the via conductor 40 also is decreased in diameter. The inner wall surface 27 of the via hole 26 includes the first inclined surface (27A), the second inclined surface (27B), and the step surface (27C). The second inclination angle (02) of the second inclined surface (27B) is larger than the first inclination angle (01) of the first inclined surface (27A). As a result, the bottom part (40B) of the via conductor 40 is optimized in size.

As illustrated in FIG. 1, the second conductor layer 30 is formed on the first surface 22 of the resin insulating layer 20. The second conductor layer 30 includes a first signal wiring 32, a second signal wiring 34, and a land 36. The second conductor layer 30 may also include a conductor circuit other than the first signal wiring 32, the second signal wiring 34, and the land 36. The first signal wiring 32 and the second signal wiring 34 form a pair wiring. The second conductor layer 30 is mainly formed of copper. The second conductor layer 30 is formed of a seed layer (30a) on the first surface 22 and an electrolytic plating layer (30b) on the seed layer (30a). The seed layer (30a) is formed of a first seed layer (31a) on the first surface 22 and a second seed layer (31b) on the first seed layer (31a). The first seed layer (31a) is formed of an alloy (copper alloy) containing copper, silicon, and aluminum. The second seed layer (31b) is formed of copper. The electrolytic plating layer (30b) is formed of copper. The first seed layer (31a) is in contact with the first surface 22. The second seed layer (31b) adheres to the electrolytic plating layer (30b). A surface of the second conductor layer 30 facing the first surface 22 of the resin insulating layer 20 is formed along a surface shape of the first surface 22. The second conductor layer 30 does not enter an inner side of the first surface 22 of the resin insulating layer 20.

The via conductor 40 is formed in the via hole 26. The via conductor 40 connects the first conductor layer 10 and the second conductor layer 30, which are adjacent to each other in a lamination direction. The lamination direction is a direction in which the layers are laminated and is the same direction as the thickness direction of the layers. In the present embodiment, the lamination direction is the same as an up-down direction. In FIG. 1, the via conductor 40 connects the pad 14 and the land 36. The via conductor 40 is formed of a seed layer (30a) and an electrolytic plating layer (30b) on the seed layer (30a). The seed layer (30a) forming the via conductor 40 and the seed layer (30a) forming the second conductor layer 30 are common. The first seed layer (31a) is in contact with the inner wall surface 27.

A coating film layer 35 is formed on the surfaces of the resin insulating layer 20 and the second conductor layer 30. The coating film layer 35 increases adhesion of the resin insulating layer 20 and the second conductor layer 30 to other layers laminated on the resin insulating layer 20 and the second conductor layer 30. The coating film layer 35 may be omitted.

### Method for Manufacturing Printed Wiring Board

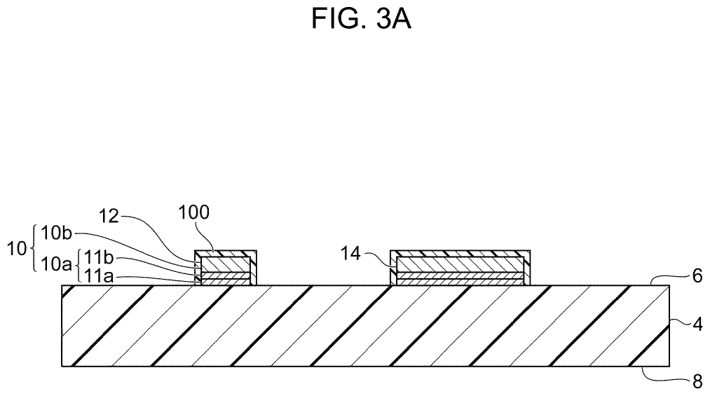

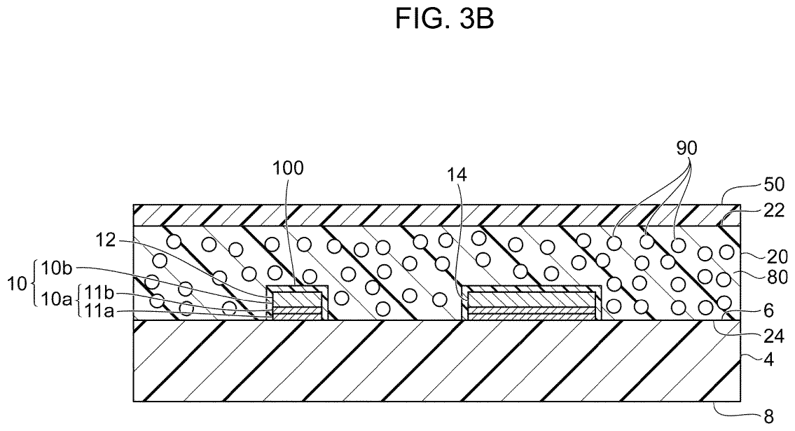

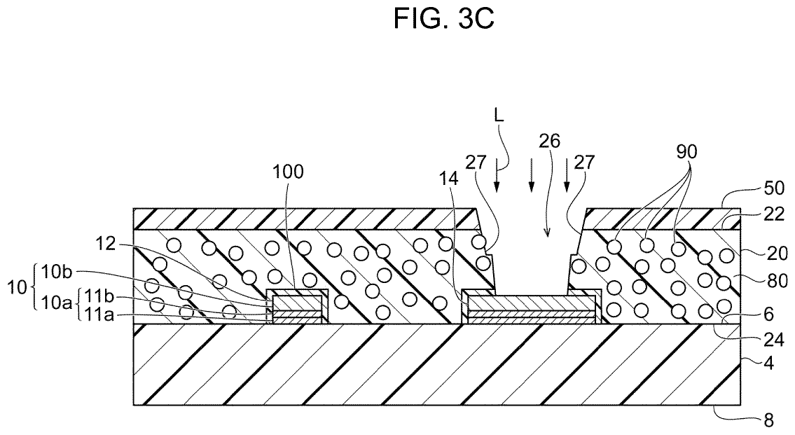

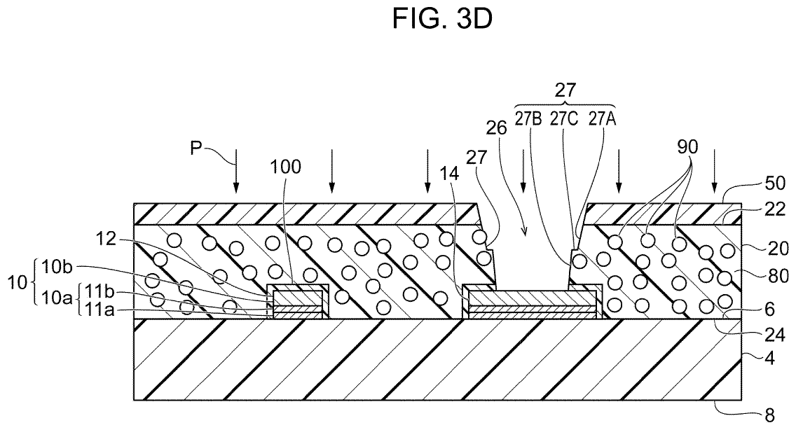

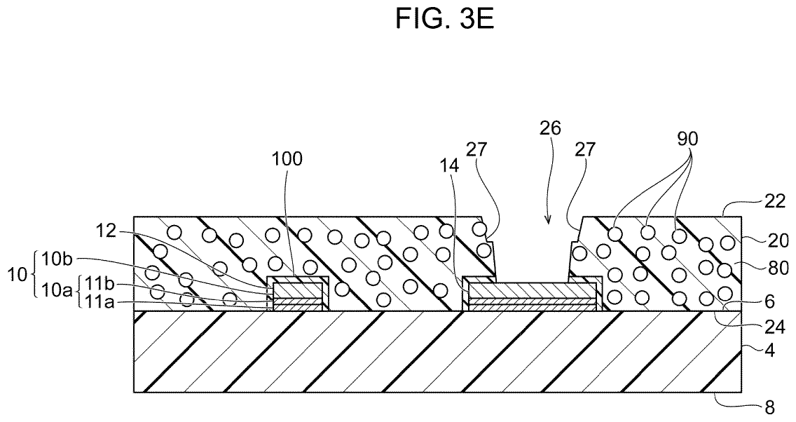

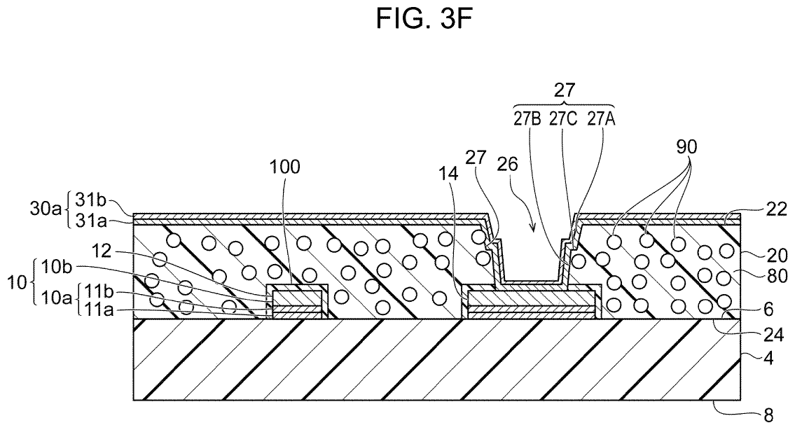

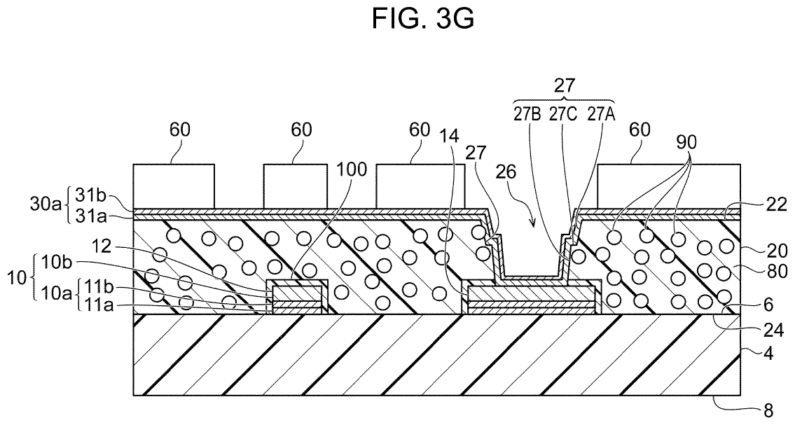

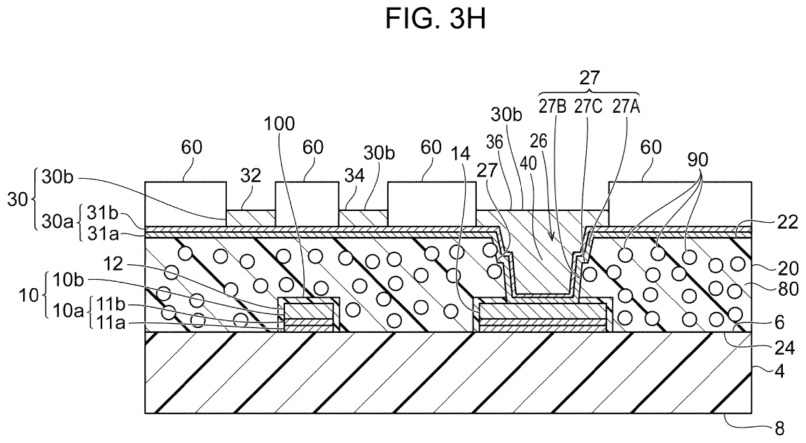

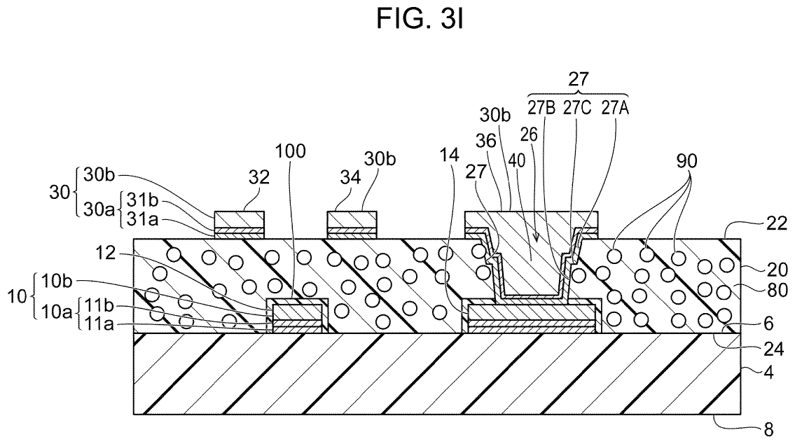

FIGS. 3A-3I illustrate a method for manufacturing the printed wiring board 2 of the embodiment. FIGS. 3A-3I are cross-sectional views. FIG. 3A illustrates the first conductor layer 10 and the adhesive layer 100. The first conductor layer 10 is formed on the third surface 6 of the insulating layer 4. The adhesive layer 100 covers the surface of the first conductor layer 10. The first conductor layer 10 is formed using a semi-additive method. The adhesive layer 100 is formed by immersing the insulating layer 4 and the first conductor layer 10 in a chemical solution containing a nitrogen-based organic compound. Or, the adhesive layer 100 is formed by applying the above chemical liquid onto the first conductor layer 10.

As illustrated in FIG. 3B, the resin insulating layer 20 and a protective film 50 are formed on the insulating layer 4 and the first conductor layer 10, which is covered by the adhesive layer 100. The second surface 24 of the resin insulating layer 20 faces the third surface 6 of the insulating layer 4. The protective film 50 is formed on the first surface 22 of the resin insulating layer 20. The resin insulating layer 20 contains the resin 80 and the inorganic particles 90. The inorganic particles 90 are embedded in the resin 80. The first surface 22 of the resin insulating layer 20 is formed only of the resin 80. No inorganic particles 90 are exposed from the first surface 22. The first surface 22 does not include surfaces of the inorganic particles 90. No unevenness is formed on the first surface 22 of the resin insulating layer 20.

The protective film 50 completely covers the first surface 22 of the resin insulating layer 20. The protective film 50 is, for example, a film formed of polyethylene terephthalate (PET). A layer of a release agent is formed between the protective film 50 and the resin insulating layer 20.

As illustrated in FIG. 3C, laser (L) is irradiated from above the protective film 50.

The laser (L) penetrates the protective film 50 and the resin insulating layer 20 at the same time. The via hole 26 for a via conductor reaching the adhesive layer 100 covering the pad 14 is formed. The laser (L) is, for example, UV laser, or CO₂ laser. The via hole 26 has the inner wall surface (27C) that includes the first inclined surface (27A), the second inclined surface (27B), and the step surface (27C) (FIG. 3D).

The adhesive layer 100 is not completely removed by the laser (L). The adhesive layer 100 covering the pad 14 is exposed by the via hole 26. When the via hole 26 is formed, the first surface 22 of the resin insulating layer 20 is covered by the protective film 50. Therefore, when the via hole 26 is formed, even when the resin scatters, adherence of the resin to the first surface 22 is suppressed. The inner wall surface 27 of the via hole 26 after the laser irradiation is formed of the resin 80 and the inorganic particles 90 protruding from the resin 80.

As illustrated in FIG. 3D, the inside of the via hole 26 is cleaned. The adhesive layer 100 exposed from the via hole 26 is removed by cleaning the inside of the via hole 26. The pad 14 is exposed from the via hole 26. Resin residues generated during the formation of the via hole 26 are removed. The cleaning of the inside of the via hole 26 is performed using plasma (P). That is, the cleaning is performed with a dry process. A gas of the dry process is a mixed gas of a halogen-based gas (such as a fluorine-based gas or a chlorine-based gas) and an O₂ gas or is a halogen-based gas (such as a fluorine-based gas or a chlorine-based gas) or an O₂ gas alone. The cleaning includes a desmear treatment. The adhesive layer 100 formed between the second surface 24 of the resin insulating layer 20 and the pad 14 is not removed. Therefore, no gap is formed between the second surface 24 of the resin insulating layer 20 and the pad 14.

The plasma (P) selectively removes the resin 80. The plasma (P) removes the resin 80 faster than the inorganic particles 90. By cleaning the inside of the via hole 26, the inorganic particles 90 are exposed on the inner wall surface 27 of the via hole 26 (FIG. 3C). The inner wall surface 27 of the via hole 26 includes surfaces of the inorganic particles 90. Unevenness is formed on the inner wall surface 27 of the via hole 26. On the other hand, the first surface 22 of the resin insulating layer 20 is covered by the protective film 50. The first surface 22 is not affected by the plasma (P). The first surface 22 is formed of the resin 80 only. No inorganic particles 90 are exposed from the first surface 22. The first surface 22 does not include surfaces of the inorganic particles 90. No unevenness is formed on the first surface 22 of the resin insulating layer 20. The first surface 22 is formed smooth.

As illustrated in FIG. 3E, after cleaning the inside of the via hole 26, the protective film 50 is removed from the resin insulating layer 20. After the protective film 50 is removed, no roughening of the first surface 22 of the resin insulating layer 20 is performed. The first surface 22 is formed smooth. The first surface 22 has, for example, an arithmetic mean roughness (Ra) of 0.02 μm or more and 0.06 μm or less.

As illustrated in FIG. 3F, the seed layer (30a) is formed on the first surface 22 of the resin insulating layer 20 and on the inner wall surface 27. The seed layer (30a) is formed by sputtering. The seed layer (30a) is a sputtered film. The formation of the seed layer (30a) is performed with a dry process. The first seed layer (31a) is formed on the first surface 22 by sputtering. At the same time, the first seed layer (31a) is formed on the inner wall surface 27 and the pad 14, which are exposed from the via hole 26, by sputtering. After that, the second seed layer (31b) is formed on the first seed layer (31a) by sputtering. The first seed layer (31a) and the second seed layer (31b) are formed of a combination of copper alloys of different materials, or a combination of a copper alloy and copper. The first seed layer (31a) is formed of a copper alloy. A combination of a copper alloy and the resin insulating layer 20 has a higher adhesion than a combination of copper and the resin insulating layer 20. The second seed layer (31b) is formed of a copper alloy or copper. The copper alloys of the first seed layer (31a) and the second seed layer (31b) have a copper content of 90% or more of a total weight. Since the higher the copper content is, the lower the electrical resistance can be reduced, connection reliability can be improved. The seed layer (30a) is also formed on the upper surface of the pad 14 exposed from the via hole 26 and on the inner wall surface 27 of the via hole 26. The first seed layer (31a) is formed of an alloy containing copper, silicon and aluminum. The second seed layer (31b) is formed of copper.

As illustrated in FIG. 3G, a plating resist 60 is formed on the seed layer (30a). Since the first surface 22 of the resin insulating layer 20 is not roughened, the seed layer (30a) can be formed to have a uniform thickness on a low-roughness surface. Since the plating resist 60 can tightly adhere to the seed layer (30a) without a gap, peeling of the plating resist 60 can be prevented and a short circuit between wirings during electrolytic plating formation can be suppressed. The plating resist 60 has openings for forming the first signal wiring 32, the second signal wiring 34, and the land 36 (see FIG. 1).

As illustrated in FIG. 3H, the electrolytic plating layer (30b) is formed on the seed layer (30a) exposed from the plating resist 60. The electrolytic plating layer (30b) is formed of copper. The electrolytic plating layer (30b) fills the via hole 26. When the third inclination angle (θ3) of the step surface (27C) is zero or a positive value, the via hole 26 is likely to be filled with the electrolytic plating layer (30b) without any gap. The first signal wiring 32, the second signal wiring 34, and the land 36 are formed by the seed layer (30a) and the electrolytic plating film (30b) on the first surface 22. The second conductor layer 30 is formed. The via conductor 40 is formed by the seed layer (30a) and the electrolytic plating film (30b) in the via hole 26. The second conductor layer 30 and the via conductor 40 are formed at the same time. The via conductor 40 connects the pad 14 and the land 36. The first signal wiring 32 and the second signal wiring 34 form a pair wiring.

As illustrated in FIG. 31, the plating resist 60 is removed. The seed layer (30a) exposed from the electrolytic plating layer (30b) is removed. The surface of the second conductor layer 30 is adjusted to have an arithmetic mean roughness (Ra) in a range of 0.02 μm or more and 0.5 μm or less by removing the seed layer (30a) with an etching solution. The first conductor layer 10 with a rough surface can reduce transmission loss. The second conductor layer 30 and the via conductor 40 are formed at the same time.

After that, when necessary, an O₂ ashing treatment is performed with respect to the first surface 22 of the resin insulating layer 20. In the O₂ ashing treatment, the first surface 22 of the resin insulating layer 20 is irradiated with O₂ plasma.

After that, the second conductor layer 30 is further subjected to a chemical conversion treatment. For example, the coating film layer 35 is formed on the surfaces of the resin insulating layer 20 and the second conductor layer 30. The printed wiring board 2 of the embodiment (see FIG. 1) is obtained.

In the printed wiring board 2 of the embodiment (see FIGS. 1-2B), the inner wall surface 27 of the via hole 26 has the first inclined surface (27A) and the second inclined surface (27B). Compared to a structure where the first inclined surface (27A) extends all the way to the pad 14 without having the second inclined surface (27B), the bottom part (40B) of the via conductor 40 is decreased in diameter. In a structure where the pad 14 is miniaturized, even when the position of the via conductor 40 is misaligned, the bottom part (40B) of the via conductor 40 can be prevented from protruding laterally beyond the upper surface of the pad 14. Since the bottom part (40B) of the via conductor 40 does not protrude beyond the upper surface of the pad 14, connectivity of the via conductor 40 to the pad 14 is improved. Due to miniaturization, the pads 14 can be arranged at a high density.

In the printed wiring board 2 of the embodiment (see FIGS. 1-2B), the second inclination angle (θ2) of the second inclined surface (27B) is larger than the inclination angle (θ1) of the first inclined surface (27A). When the bottom part (40B) of the via conductor 40 is kept constant, compared to a structure where the second inclination angle (θ2) of the second inclined surface (27B) is equal to or smaller than the first inclination angle (θ1) of the first inclined surface (27A), an upper part of the second inclined surface (27B) has a smaller diameter. Since the upper part of the second inclined surface 27 has a small diameter, a volume of a space of the second inclined surface (27B) in the via hole 26 is reduced. Therefore, the via hole 26 can be easily filled with plating.

In the printed wiring board 2 of the embodiment (see FIGS. 1-2B), the inner wall surface 27 of the via hole 26 is formed of the resin 80 and the inorganic particles 90. The inner wall surface 27 is a non-roughened surface without being roughened. Since the inner wall surface 27 is a non-roughened surface, the surface of the seed layer (30a) is smooth. As a result, a filling property of the electrolytic plating layer (30b) is improved. Formation of a stress concentration site (for example, an uneven part) in the electrolytic plating layer (30b) that forms an inner layer of the via conductor 40 is suppressed. As a result, occurrence of a crack in the electrolytic plating layer (30b), which is an inner layer of the via conductor 40, can be suppressed. Further, since the inner wall surface 27 is a non-roughened surface, occurrence of a void between the inner wall surface 27 and the via conductor 40 is suppressed.

In the printed wiring board 2 of the embodiment (see FIG. 1), the first surface 22 of the resin insulating layer 20 is formed of the resin 80. The inorganic particles 90 are not exposed on the first surface 22. No unevenness is formed on the first surface 22. An increase in standard deviation of a relative permittivity in a portion near the first surface 22 of the resin insulating layer 20 is suppressed. The relative permittivity of the first surface 22 does not significantly vary depending on a location. Even when the first signal wiring 32 and the second signal wiring 34 are in contact with the first surface 22, a difference in propagation speed of an electrical signal between the first signal wiring 32 and the second signal wiring 34 can be reduced. Therefore, in the printed wiring board 2 of the embodiment, noise is suppressed. Even when a logic IC is mounted on the printed wiring board 2 of the embodiment, data transmitted via the first signal wiring 32 and data transmitted via the second signal wiring 34 arrive at the logic IC substantially without delay. Malfunction of the logic IC can be suppressed. Even when a length of the first signal wiring 32 and a length of the second signal wiring 34 are 5 mm or more, a difference in propagation speed between the two can be reduced. Even when the length of the first signal wiring 32 and the length of the second signal wiring 34 are 10 mm or more and 20 mm or less, malfunction of the logic IC can be suppressed. A high quality printed wiring board 2 is provided.

In the printed wiring board 2 of the embodiment (see FIG. 1), the thickness (T) of the resin insulating layer 20 is two or more times the thickness of the second conductor layer 30. It is thought that, when the printed wiring board 2 is subjected to heat cycles, a stress applied between the inner wall surface 27 of the via hole 26 and the via conductor 40 is greater than a stress applied between the first surface 22 and the second conductor layer 30. Further, when the inorganic particles 90 are present on the inner wall surface 27 of the via hole 26, there is a concern that adhesion strength between the inner wall surface 27 of the via hole 26 and the via conductor 40 may decrease. However, the presence of the base layer 33 suppresses a decrease in the adhesion strength between the inner wall surface 27 of the via hole 26 and the via conductor 40. The via conductor 40 is unlikely to peel off from the resin insulating layer 20.

In the printed wiring board 2 of the embodiment, the seed layer (30a) is formed by sputtering (see FIG. 3E). Particles forming the seed layer (30a) perpendicularly collide with the first surface 22. Therefore, adhesion strength between the first surface 22 and the seed layer (30a) is high. On the other hand, the particles forming the seed layer (30a) obliquely collide with the inner wall surface 27 of the via hole 26. However, the inner wall surface 27 of the via hole 26 has unevenness. Therefore, adhesion strength between the seed layer (30a) and the inner wall surface 27 of the via hole 26 is high. Even when the first surface 22 does not have unevenness and the inner wall surface 27 of the via hole 26 has unevenness, a difference between the adhesion strength between the second conductor layer 30 and the first surface 22 and the adhesion strength between the via conductor 40 and the inner wall surface 27 of the via hole 26 can be reduced. A stress is unlikely to concentrate on an interface between the second conductor layer 30 and the first surface 22. A stress is unlikely to concentrate on an interface between the via conductor 40 and the inner wall surface 27 of the via hole 26. Even when the printed wiring board 2 is subjected to heat cycles, the via conductor 40 is unlikely to peel off from the resin insulating layer 20. A high quality printed wiring board 2 is provided.

The first seed layer (31a) of the seed layer (30a) is formed of copper and a second element. The second element is selected from silicon, aluminum, titanium, nickel, chromium, carbon, oxygen, tin, calcium, magnesium, iron, molybdenum, and silver. The first seed layer (31a) is formed of an alloy containing copper. The second seed layer (31b) is formed of copper. An amount of copper (atomic weight %) forming the second seed layer (31b) is 99.9% or more, and preferably 99.95% or more.

It is also possible that the first seed layer (31a) of the seed layer (30a) is formed of any one of silicon, aluminum, titanium, nickel, chromium, carbon, oxygen, tin, calcium, magnesium, iron, molybdenum, and silver.

In the printed wiring board 2, the resin insulating layer 20 contains the resin 80 and the inorganic particles 90. However, the resin insulating layer 20 may also contain a fiber reinforcing material. As the fiber reinforcing material, for example, a glass cloth, a glass nonwoven fabric, or an aramid nonwoven fabric may be used.

In the printed wiring board 2, one resin insulating layer is laminated. However, it is also possible that two or more resin insulating layers are laminated.

A printed wiring board according to an embodiment of the present invention is not limited to those having the structures exemplified in the drawings and those having the structures, shapes, and materials exemplified in the present specification. As described above, the printed wiring board of the embodiment can have any laminated structure. For example, the wiring substrate of the embodiment may be a coreless substrate that does not include a core substrate. A printed wiring board according to an embodiment of the present invention may include any number of conductor layers and any number of insulating layers.

A method for manufacturing a printed wiring board according to an embodiment of the present invention is not limited to the method described with reference to the drawings. For example, the insulating layers can each be formed using a resin in any form without being limited to a film-like resin. In the method for manufacturing the printed wiring board of the embodiment, it is also possible that any process other than the processes described above is added, or some of the processes described above are omitted.

Japanese Patent Application Laid-Open Publication No. 2009-302588 describes a multilayer printed wiring board in which interlayer resin insulating layers and conductor circuits are alternately laminated, and an upper-layer conductor circuit and a lower-layer conductor circuit are connected by a via hole. The via hole described in Japanese Patent Application Laid-Open Publication No. 2009-302588 has a shape that decreases in diameter from the upper-layer conductor circuit toward the lower-layer conductor circuit. For a via conductor formed in a via hole of a resin insulating layer, it is desirable to increase connectivity to a conductor layer.

A printed wiring board according to an embodiment of the present invention includes: a first conductor layer; a resin insulating layer that has a first surface and a second surface on the opposite side with respect to the first surface, is formed on the first conductor layer with the second surface facing the first conductor layer, and has a via hole exposing the first conductor layer; a second conductor layer that is formed on the first surface of the resin insulating layer; and a via conductor that is formed in the via hole, penetrates the resin insulating layer, and connects the first conductor layer and the second conductor layer. An inner wall surface of the via hole has: a first inclined surface that decreases in diameter from the first surface side to a middle portion in a thickness direction of the resin insulating layer; a second inclined surface that decreases in diameter from the middle portion side to the second surface side with a smaller diameter than an end part of the first inclined surface on the middle portion side; and a step surface that continuously connects between the first inclined surface and the second inclined surface.

According to an embodiment of the present invention, for a via conductor, connectivity to a conductor layer is improved.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
a first conductor layer;
a resin insulating layer formed on the first conductor layer;
a second conductor layer formed on the resin insulating layer; and
a via conductor formed in the resin insulating layer such that the via conductor is penetrating through the resin insulating layer and connecting the first conductor layer and the second conductor layer,
wherein the resin insulating layer has a via hole in which the via conductor is formed such that an inner wall surface in the via hole has a first inclined surface decreasing in diameter from the second conductor layer to a middle portion of the via hole in a thickness direction of the resin insulating layer, a second inclined surface decreasing in diameter from the middle portion to the first conductor layer with a smaller diameter than an end part of the first inclined surface in the middle portion, and a step surface connecting the first inclined surface and the second inclined surface.

2. The printed wiring board according to claim 1, wherein the resin insulating layer is formed such that the via hole has a first inclination angle of the first inclined surface with respect to the first conductor layer and a second inclination angle of the second inclined surface with respect to the first conductor layer and that the second inclination angle is larger than the first inclination angle.

3. The printed wiring board according to claim 1, wherein the resin insulating layer is formed such that the inner wall surface in the via hole is a non-roughened surface.

4. The printed wiring board according to claim 1, wherein the resin insulating layer includes resin and inorganic particles and is formed such that the inner wall surface in the via hole includes the resin and the inorganic particles.

5. The printed wiring board according to claim 1, wherein the via conductor includes a seed layer formed on the inner wall surface in the via hole and a metal layer on the seed layer.

6. The printed wiring board according to claim 5, wherein the seed layer includes a sputtered layer.

7. The printed wiring board according to claim 5, wherein the via conductor is formed such that the metal layer includes an electrolytic plating layer filling the via hole formed in the resin insulating layer.

8. The printed wiring board according to claim 2, wherein the resin insulating layer is formed such that the inner wall surface in the via hole is a non-roughened surface.

9. The printed wiring board according to claim 2, wherein the resin insulating layer includes resin and inorganic particles and is formed such that the inner wall surface in the via hole includes the resin and the inorganic particles.

10. The printed wiring board according to claim 2, wherein the via conductor includes a seed layer formed on the inner wall surface in the via hole and a metal layer on the seed layer.

11. The printed wiring board according to claim 10, wherein the seed layer includes a sputtered layer.

12. The printed wiring board according to claim 10, wherein the via conductor is formed such that the metal layer includes an electrolytic plating layer filling the via hole formed in the resin insulating layer.

13. The printed wiring board according to claim 3, wherein the resin insulating layer includes resin and inorganic particles and is formed such that the inner wall surface in the via hole includes the resin and the inorganic particles.

14. The printed wiring board according to claim 3, wherein the via conductor includes a seed layer formed on the inner wall surface in the via hole and a metal layer on the seed layer.

15. The printed wiring board according to claim 14, wherein the seed layer includes a sputtered layer.

16. The printed wiring board according to claim 14, wherein the via conductor is formed such that the metal layer includes an electrolytic plating layer filling the via hole formed in the resin insulating layer.

17. The printed wiring board according to claim 4, wherein the via conductor includes a seed layer formed on the inner wall surface in the via hole and a metal layer on the seed layer.

18. The printed wiring board according to claim 17, wherein the seed layer includes a sputtered layer.

19. The printed wiring board according to claim 17, wherein the via conductor is formed such that the metal layer includes an electrolytic plating layer filling the via hole formed in the resin insulating layer.

20. The printed wiring board according to claim 6, wherein the via conductor is formed such that the metal layer includes an electrolytic plating layer filling the via hole formed in the resin insulating layer.
